(19) United States
(12) Patent Application Publication
(10) Pub. No.: US 2015/0325684 A1
(43) Pub. Date: Nov. 12, 2015

(54) MANUFACTURING METHOD OF N-TYPE MOSFET

(71) Applicant: Institute of Microelectronics, Chinese Academy of Sciences, Beijing (CN)

(72) Inventors: Qiuxia Xu, Beijing (CN); Gaobo Xu, Beijing (CN); Huajie Zhou, Beijing (CN); Huilong Zhu, Poughkeepsie, NY (US)

(21) Appl. No.: 14/375,738

(22) PCT Filed: Dec. 7, 2012
(86) PCT No.: PCT/CN2012/086151

§ 371 Date: Jul. 24, 2015

(30) Foreign Application Priority Data
Nov. 30, 2012 (CN) 201210506466.X

(51) Int. Cl. H01L 29/66; H01L 21/324; H01L 21/225; H01L 29/167; H01L 21/02; H01L 21/28; H01L 29/423; H01L 29/51; H01L 21/265

(52) U.S. Cl. CPC H01L 29/66568; H01L 29/517; H01L 21/324; H01L 21/2254; H01L 21/265; H01L 21/02057; H01L 21/28185; H01L 29/518; H01L 21/02266; H01L 21/0228; H01L 21/02271; H01L 29/42364; H01L 29/167

(57) ABSTRACT

A method for manufacturing an NMOSFET may comprise: defining an active region for the NMOSFET on a semiconductor substrate; forming an interfacial oxide layer on a surface of the semiconductor substrate; forming a high-K gate dielectric layer on the interfacial oxide layer; forming a metal gate layer on the high-K gate dielectric layer; implanting dopant ions into the metal gate layer; forming a Poly-Si layer on the metal gate layer; patterning the Poly-Si layer, the metal gate layer, the high-K gate dielectric layer and the interfacial oxide layer to form a gate stack; forming a gate spacer surrounding the gate stack; and forming source and drain regions. During annealing for the S/D activation to form the S/D regions, the dopant ions implanted in the metal gate layer may accumulate at both interfaces of the upper interface and the bottom interface of High K dielectric, and electric dipoles with appropriate polarities are generated by interface reaction at the bottom interface, so that the metal gate of the NMOSFET may have its effective work function adjusted.

### CROSS-REFERENCE TO RELATED APPLICATION

This application is a National Phase application of PCT Application No. PCT/CN2012/086151, filed on Dec. 7, 2012, entitled “METHOD FOR MANUFACTURING N-TYPE MOSFET,” which claimed priority to Chinese Application No. 201210506466.X, filed on Nov. 30, 2012. Both the PCT Application and the Chinese Application are incorporated herein by reference in their entireties.

### TECHNICAL FIELD

The present disclosure relates to the semiconductor technology, and particularly to a method for manufacturing an N-type MOSFET (NMOSFET) including a metal gate and a high-K gate dielectric layer.

### BACKGROUND

As the development of the semiconductor technology, Metal Oxide Semiconductor Field Effect Transistors (MOSFETs) have their feature sizes being decreased continuously. The decrease in size of the MOSFETs causes a severe problem of gate current leakage. The gate leakage current can be reduced by using a high-K gate dielectric layer, which may have an increased physical thickness with respect to a given equivalent oxide thickness (EOT). Unfortunately, a conventional Poly-Si gate is incompatible with the high-K gate dielectric layer. By using a combination of a metal gate and the high-K gate dielectric layer, it is possible not only to avoid the depletion effect of the Poly-Si gate and decrease gate resistance, but also to avoid boron penetration and enhance device reliability. Therefore, the combination of the metal gate and the high-K gate dielectric layer is widely used in the MOSFETs. However, integration of the metal gate and the high-K gate dielectric layer is still confronted with many challenges, such as thermal stability and interfacial states. Particularly, due to the Fermi-Pinning Effect, it is difficult for the MOSEFTs using the metal gate and the high-K gate dielectric layer to have a properly low threshold voltage.

To obtain an appropriate threshold voltage, an NMOSFET should have its effective work function near the bottom of the conduction band of Si (about 4.1 eV). It is desirable to select an appropriate combination of a metal gate and a high-K gate dielectric layer for the NMOSFET, so as to achieve the desired threshold voltage. However, it is difficult to obtain such a low effective work function simply by altering materials.

### SUMMARY

The present disclosure intends to provide, among others, a method for manufacturing an NMOSFET, by which it is possible to adjust an effective work function of the NMOSFET during manufacture thereof.

According to an aspect of the present disclosure, there is provided a method for manufacturing an NMOSFET, comprising: defining an active region for the NMOSFET on a semiconductor substrate; forming an interfacial oxide layer on a surface of the semiconductor substrate; forming a high-K gate dielectric layer on the interfacial oxide layer; forming a metal gate layer on the high-K gate dielectric layer; implanting dopant ions into the metal gate layer; forming a Poly-Si layer on the metal gate layer; patterning the Poly-Si layer, the metal gate layer, the high-K gate dielectric layer and the interfacial oxide layer to form a gate stack; forming a gate spacer surrounding the gate stack; and forming S/D regions, wherein during annealing for activation to form the S/D regions, the dopant ions in the metal gate layer diffuse and accumulate at an upper interface between the high-K gate dielectric layer and the metal gate layer and at a lower interface between the high-K gate dielectric layer and the interfacial oxide layer, and electric dipoles are generated by interfacial reaction at the lower interface between the high-K gate dielectric layer and the interfacial oxide layer.

In accordance with this method, the dopant ions accumulated at the upper interface of the high-K gate dielectric layer can change characteristics of the metal gate, thereby adjusting the effective work function of the NMOSFET advantageously. On the other hand, the dopant ions accumulated at the lower interface between the high-K gate dielectric layer and the interfacial oxide layer at the side of the high-K gate dielectric layer can form electric dipoles having appropriate polarities by the interfacial reaction, thereby further adjusting the effective work function of the NMOSFET advantageously. The NMOSFET obtained by this method has good stability, and the effective work function of the metal gate can be advantageously adjusted.

### BRIEF DESCRIPTION OF THE DRAWINGS

In order to provide a thorough understanding of the present disclosure, the present disclosure will be explained in detail with reference to the accompanying drawings.

FIGS. 1-7 schematically show sectional views of respective semiconductor structures during each stage of manufacturing an NMOSFET according to an embodiment of the present disclosure.

### DETAILED DESCRIPTION

Next, the present disclosure will be explained in detail with reference to the accompanying drawings. In the following description, like components are represented by like or similar reference signs, regardless of whether they are shown in different embodiments. The drawings are not drawn to scale for the sake of clarity.

In the following description, some specific details are set forth, such as structures, materials, sizes, and treatment processes and technologies of devices, in order to provide a thorough understanding of the present disclosure. However, it will be understood by those of ordinary skill in the art that the present disclosure may be practiced without these specific details. Each portion of a semiconductor device may comprise materials well known to those of ordinary skill in the art, or materials having similar functions to be developed in future, unless noted otherwise.

In the present disclosure, the term “semiconductor structure” refers to a semiconductor substrate and all layers or regions formed on the semiconductor substrate obtained after some operations during a process of manufacturing a semiconductor device. The term “SID region” refers to either a source region or a drain region of a MOSFET, and both of the source region and the drain region are labeled with a single reference sign. The term “N-type dopant” refers to a dopant applicable to an NMOSFET to decrease its effective work function.

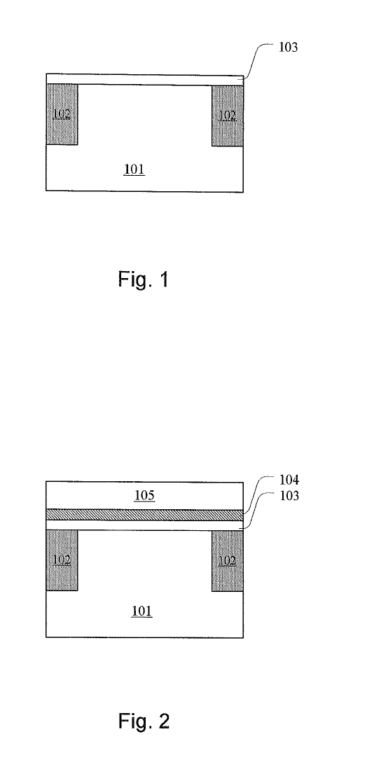

A method for manufacturing an NMOSFET in a gate first process according to an embodiment of the present disclosure will be illustrated with reference to FIGS. 1-7.

FIG. 1 shows a semiconductor structure, which has gone through part of the gate first process. Specifically, on a semiconductor substrate 101 (e.g., a Si substrate), an active region for the NMOSFET is defined by shallow trench isolation 102.

An interfacial oxide layer 103 (e.g., a silicon oxide layer) is formed on an exposed surface of the semiconductor substrate 101 by chemical oxidation or additional thermal oxidation. In an example, the interfacial oxide layer 103 may be formed by rapid thermal oxidation for 20-120 seconds at a temperature of about 600-900° C. In another example, the interfacial oxide layer 103 may be formed by chemical oxidation in water solution containing ozone (O₃).

Preferably, the surface of the semiconductor substrate 101 may be cleaned before the interfacial oxide layer 103 is formed. Cleaning the semiconductor substrate 101 may comprise cleaning the semiconductor substrate 101 by conventional methods and then immersing the semiconductor substrate 101 into mixed solution including hydrofluoric acid, isopropanol and water. After that, the semiconductor substrate 101 may be rinsed with deionized water, and then spin-dried. In an example, the hydrofluoric acid, isopropanol and water in the mixed solution may have a volume ratio of about 0.2-1.5%:0.01-0.10%:1, and the immersing may be performed for about 1-10 minutes. With the cleaning process, the surface of the semiconductor substrate 101 can be cleaned, thereby inhibiting particle contamination and natural oxidation re-growth on the silicon surface, and thus facilitating formation of the interfacial oxide layer 103 with high quality.

Then, by a known deposition process, such as ALD (atomic layer deposition), CVD (chemical vapor deposition), MOCVD (metal organic chemical vapor deposition), PVD (physical vapor deposition), sputtering and or the like, a high-K gate dielectric layer 104 and a metal gate layer 105 are formed on the surface of the semiconductor structure in sequence, as shown in FIG. 2.

The high-K gate dielectric layer 104 may comprise any appropriate material with a dielectric constant greater than that of SiO₂, such as any one selected from a group of ZrO₂, ZrON, ZrSiON, HfZrO, HfZrON, HfON, HfO₂, HfAlO, HfAlON, HfSiO, HfSiON, HfLaO, HfLaON, or any combination thereof. The metal gate layer 105 may comprise any appropriate material capable of forming a metal gate, such as any one selected from TiN, TaN, MoN, WN, TaC, or TaCN. In an example, the high-K gate dielectric layer 104 may comprise a HfO₂ layer with a thickness of about 1.5-5 nm, and the metal gate layer 105 may comprise a TiN layer with a thickness of about 2-30 nm.

Preferably, post-deposition-annealing of the high-K gate dielectric layer may be performed between the operations of forming the high-K gate dielectric layer 104 and forming the metal gate layer 105, so as to improve quality of the high-K gate dielectric layer, which facilitates the metal gate layer 105 formed subsequently to have a uniform thickness. In an example, rapid thermal annealing may be performed at a temperature of about 500-1000° C. for about 5-100 seconds as the post-deposition-annealing.

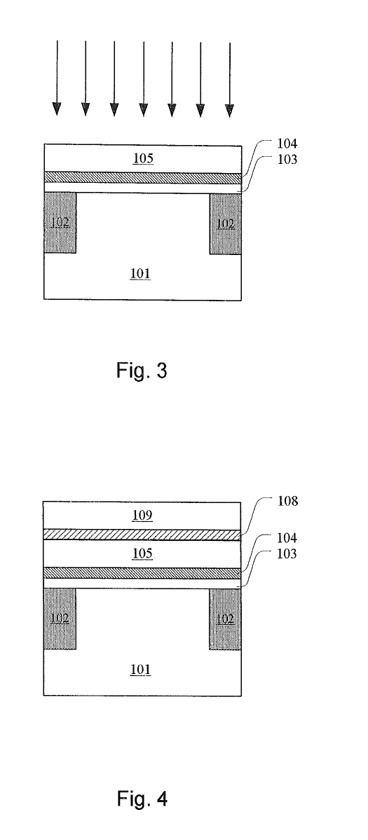

Then, N-type dopants are implanted into the metal gate layer 105 at the active region of the NMOSFET, as shown in FIG. 3. The N-type dopant for the metal gate may comprise any one selected from a group of P, As, Sb, La, Er, Dy, Gd, Sc, Yb, Er or Tb. Energy and dose for the ion implantation may be controlled so that the implanted dopant ions are distributed substantially only in the metal gate layer 105, without entering the high-K gate dielectric layer 104. The energy and dose for the ion implantation may be further controlled so that the metal gate layer 105 has suitable doping depth and concentration in order to achieve a desired threshold voltage. In an example, the energy of the ion implantation may be about 0.2 KeV-30 KeV, and the dose of the ion implantation may be about 1E13-1E15 cm⁻².

Then, by any of the aforementioned deposition processes, a metal barrier layer 108 and a Poly-Si layer 109 are formed on the surface of the semiconductor structure in sequence, as shown in FIG. 4. The metal barrier layer 108 may comprise any material capable of blocking reaction and mutual-diffusion between the Poly-Si layer 109 and the metal gate layer 105, such as any one selected from a group of TaN, AlN or TiN. It is to be noted that the metal barrier layer 108 is optional. The metal barrier layer 108 is not necessary if there is substantially no reaction and mutual-diffusion between the Poly-Si layer 109 and the metal gate layer 105. The Poly-Si layer 109 may be doped to be electrically conductive. In an example, the metal barrier layer 108 may comprise a TaN layer with a thickness of about 3-8 nm, and the Poly-Si layer 109 may have a thickness of about 30-120 nm.

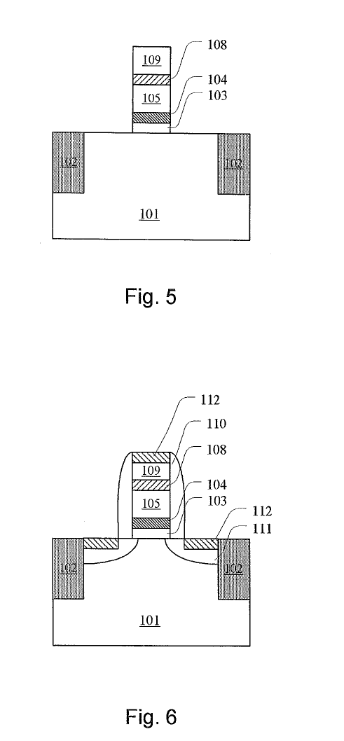

Then, a gate stack is formed by patterning with a photoresist mask (not shown) or a hard mask (not shown). During the patterning, exposed portions of the Poly-Si layer 109, the metal barrier layer 108, the metal gate layer 105, the high-K gate dielectric layer 104 and the interfacial oxide layer 103 are selectively removed by dry etching, such as ion-milling etching, plasma etching, reactive ion etching, or laser ablation, or by wet etching using etchant solution, so as to form the gate stack of the NMOSFET, as shown in FIG. 5.

During the patterning for forming the gate stack, different etchants may be applied to different layers. In an example, F-based, Cl-based, or HBr/Cl₂-based etchant gas may be applied in dry etching of the Poly-Si layer 109. BCl₃/Cl₂-based etchant gas may be applied in dry etching of the metal gate layer 105 and/or the high-K gate dielectric layer 104. Preferably, Ar and/or O₂ may be added into the aforementioned etchant gases to improve the etching characteristics. It is desirable that the etching of the gate stack results in a steep and continuous profile, has high anisotropy, and has high etching selectivity with respect to the silicon substrate in order to avoid damages to the silicon substrate.

Then, by any of the aforementioned deposition processes, a silicon nitride layer with a thickness of about 10-50 nm may be formed on the surface of the semiconductor structure. Then, the silicon nitride layer may be anisotropically etched, to form a spacer 110 surrounding the gate stack in the active region of the NMOSFET. The gate stack and the spacer are used as a hard mask to perform S/D ion implantation, and then annealing is performed for S/D activation. Therefore, S/D regions 111 of the NMOSFET are formed in the semiconductor substrate 101, as shown in FIG. 6. The S/D regions 111 of the NMOSFET are located at opposite sides of the gate stack, and may comprise respective extension regions at least partly extending to beneath the high-K gate dielectric layer 104.

The annealing for S/D activation may comprise rapid thermal annealing (RTA), spike annealing, laser annealing, or microwave annealing. The annealing may be performed at a temperature of about 950-1100° C. for about 2 ms-30 s. During the annealing for S/D activation to form the S/D regions, the dopant ions implanted in the metal gate layer diffuse and accumulate at an upper interface between the high-K gate dielectric layer and the metal gate layer and at a lower interface between the high-K gate dielectric layer and the interfacial oxide layer. The dopant ions accumulated at the upper interface of the high-K gate dielectric layer 104 can change characteristics of the metal gate, thereby adjusting the effective work function of the NMOSFET advantageously. On the other hand, the dopant ions accumulated at the lower interface of the high-K gate dielectric layer 104 can form electric dipoles with appropriate polarities by interfacial reaction, thereby further adjusting the effective work function of the NMOSFET advantageously. In this way, the effective work function of the metal gate of the NMOSFET device can be adjusted.

In addition, silicide regions 112 (e.g., nickel silicide, nickel platinum silicide) may be formed on the surfaces of the S/D regions 111 and the Poly-Si layer 109, so as to decrease serial resistance and contact resistance of the S/D regions 111 and the Poly-Si layer 109.

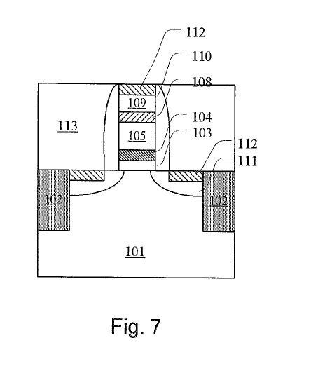

Then, by any of the aforementioned deposition processes, an interlayer dielectric layer 113 (e.g., a silicon nitride layer or a silicon oxide layer) covering the active region may be formed on the surface of the semiconductor structure. By chemical-mechanical polishing (CMP), the surface of the interlayer dielectric layer 113 is planarized, and a surface of the silicide on top of the Poly-Si layer 109 is exposed, as shown in FIG. 7. Then, contacts and metallization may be formed according to known processes.

The foregoing description does not illustrate every detail for manufacturing a MOSFET, such as formation of S/D contacts, additional interlayer dielectric layers and conductive vias. Standard CMOS processes for forming these components are well known to those of ordinary skill in the art, and thus description thereof is omitted.

The foregoing description is intended to illustrate, not limit, the present disclosure. The present disclosure is not limited to the described embodiments. Variants or modifications apparent to those skilled in the art will fall within the scope of the present disclosure.

I/We claim:

1. A method for manufacturing an NMOSFET, comprising:
defining an active region for the NMOSFET on a semiconductor substrate;
forming an interfacial oxide layer on a surface of the semiconductor substrate;
forming a high-K gate dielectric layer on the interfacial oxide layer;
forming a metal gate layer on the high-K gate dielectric layer;
implanting dopant ions into the metal gate layer;
forming a Poly-Si layer on the metal gate layer;
patterning the Poly-Si layer, the metal gate layer, the high-K gate dielectric layer and the interfacial oxide layer to form a gate stack;
forming a gate spacer surrounding the gate stack; and
forming S/D regions,
wherein during annealing for S/D activation to form the S/D regions, the dopant ions in the metal gate layer diffuse and accumulate at an upper interface between the high-K gate dielectric layer and the metal gate layer and at a lower interface between the high-K gate dielectric layer and the interfacial oxide layer, and electric dipoles are generated by interfacial reaction at the lower interface between the high-K gate dielectric layer and the interfacial oxide layer.

2. The method for manufacturing the NMOSFET according to claim 1, further comprising cleaning the surface of the semiconductor substrate between the operation of defining the active region and the operation of forming the interfacial oxide layer.

3. The method for manufacturing the NMOSFET according to claim 2, wherein the cleaning comprises:
ultrasonic-cleaning the semiconductor substrate in deionized water;
immersing the semiconductor substrate in mixed solution including hydrofluoric acid, isopropanol and water;
rinsing the semiconductor substrate with deionized water; and
spin-drying the semiconductor substrate.

4. The method for manufacturing the NMOSFET according to claim 3, wherein the hydrofluoric acid, isopropanol and water in the mixed solution have a volume ratio of about 0.2-1.5%:0.01-0.10%:1.

5. The method for manufacturing the NMOSFET according to claim 3, wherein the immersing is performed for about 2-10 minutes.

6. The method for manufacturing the NMOSFET according to claim 1, further comprising post-deposition-annealing of the high-K gate dielectric layer between the operation of forming the high-K gate dielectric layer and the operation of forming the metal gate layer, so as to improve quality of the high-K gate dielectric layer.

7. The method for manufacturing the NMOSFET according to claim 1, wherein the high-K gate dielectric layer comprises any one selected from a group of ZrO₂, ZrON, ZrSiON, HfZrO, HfZrON, HfON, HfO₂, HfAlO, HfAlON, HfSiO, HfSiON, HfLaO, HfLaON, or any combination thereof.

8. The method for manufacturing the NMOSFET according to claim 1, wherein the high-K gate dielectric layer is formed by atomic layer deposition, physical vapor deposition, or metal organic chemical vapor deposition.

9. The method for manufacturing the NMOSFET according to claim 1, wherein the high-K gate dielectric layer has a thickness of about 1.5-5 nm.

10. The method for manufacturing the NMOSFET according to claim 1, wherein the metal gate layer comprises any one selected from a group of TiN, TaN, MoN, WN, TaC, or TaCN.

11. The method for manufacturing the NMOSFET according to claim 1, wherein the metal gate layer has a thickness of about 2-30 nm.

12. The method for manufacturing the NMOSFET according to claim 1, wherein the implanting is performed at energy and dose which are controlled so that the dopant ions implanted are substantially only distributed in the metal gate layer, and are further controlled according to a desired threshold voltage.

13. The method for manufacturing the NMOSFET according to claim 12, wherein the energy is about 0.2 KeV-30 KeV.

14. The method for manufacturing the NMOSFET according to claim 12, wherein the dose is about 1E13-1E15 cm⁻².

15. The method for manufacturing the NMOSFET according to claim 1, wherein in the operation of implanting the dopant ions into the metal gate layer, a dopant is implanted to decrease an effective work function of the NMOSFET.

16. The method for manufacturing the NMOSFET according to claim 15, wherein the dopant is any one selected from a group of P, As, Sb, La, Er, Dy, Gd, Sc, Yb, Er or Tb.

17. The method for manufacturing the NMOSFET according to claim 1, further comprising forming a metal barrier layer on the metal gate layer between the operation of implanting and the operation of forming the Poly-Si layer, wherein the metal barrier layer is arranged between the metal gate layer and the Poly-Si layer formed subsequently.

18. The method for manufacturing the NMOSFET according to claim 17, wherein the metal barrier layer comprises any one selected from TaN, AlN or TiN.

19. The method for manufacturing the NMOSFET according to claim 1, wherein the annealing for activation is performed at a temperature of about 950-1100° C. for about 2 ms-30 s.

20. The method for manufacturing the NMOSFET according to claim 1, wherein the annealing for S/D activation comprises any one selected from rapid thermal annealing, spike annealing, laser annealing, or microwave annealing.
